(19) United States
(12) Patent Application Publication
(10) Pub. No.: US 2008/0088262 A1
(43) Pub. Date: Apr. 17, 2008

(54) Device and Method for Triggering a Piezo Actuator

(75) Inventor: Stephan Bolz, Pfatter (DE)

Correspondence Address: LERNER GREENBERG STEMER LLP, P O BOX 2480, HOLLYWOOD, FL, 33022-2480, US

(73) Assignee: Siemens Aktiengesellschaft

(21) Appl. No.: 11/664,492

(22) PCT Filed: Jul. 20, 2005
(86) PCT No.: PCT/EP05/53527

§ 371 Date: Apr. 2, 2007

(30) Foreign Application Priority Data
Oct. 1, 2004 (DE) 10 2004 047 961.5

(51) Int. Cl. H01L 41/04; F02D 41/20

(52) U.S. Cl. 318/116

(57) ABSTRACT

A device and a method trigger a piezo actuator by use of a DC/DC converter supplying a supply voltage at the output end, the supply voltage is applied to a series connection encompassing a high-side switching transistor and a low-side switching transistor. A series connection containing a high inductance coil and the piezo actuator that is to be triggered is disposed between the junction of the two switching transistors and a reference potential. An excitation signal having a predefined pulse duty factor (effective voltage) and a predefined switching frequency is applied to the junction in order to charge or discharge the piezo actuator.

The invention relates to a device for triggering a piezo actuator, with a DC/DC converter fed by a vehicle electrical system voltage, which delivers on its output side a high supply voltage, with an intermediate circuit capacitor being arranged between the output of the DC/DC converter and reference potential and in parallel to this a series circuit of a high-side switching transistor and of a low-side switching transistor, which is controlled via a driver circuit by means of a control signal.

The invention also relates to a method for operating this device.

The basis of the power developed by more recent designs of diesel motor vehicle essentially lies in a new fuel injection technique. In such cases injection pressures of up to 2000 bar are used in order to achieve the finest possible vaporization (atomization) of the diesel fuel and thereby a greatest possible reaction surface. The diminution of the droplet size thus achieved simultaneously causes a reduction in pollutant emissions.

However the result of the increased fuel pressure is a significantly increased fuel throughflow under otherwise comparable conditions. At the same time there is a desire, because of noise development (knocking) for example, and a further reduction in pollutants, to also inject very small amounts in the order of a few μg.

Since the maximum injection quantity is further determined however by a maximum output power of the engine, a considerable spreading of the injection volume range is produced with a simultaneous increase in the injection pressure.

Since a reduction in the size of the injection nozzle openings is subject to technical constraints, the injection time must be shortened to small injection volumes. With electromagnetic injection valves, because of the basic inductance of the coil, a rapid triggering is also subject to technical restrictions.

The triggering of fuel injection valves by means of piezo actuators has been shown to be technically viable, allowing valve actuation times in the range of 100 μs.

Voltages of typically 100V to 200 V are needed to trigger a piezo actuator for fuel injection valves. Since the impedance of a piezo actuator essentially presents itself as a capacitance of around 6.6 μF with in a resistance of around 2Ω connected in series, operation from a current source is required.

For a desired switching time of for example 200 μs and a switching voltage of 175V an effective charge current of around 6 A and a total charge of around 100 mJ will be needed.

The fuel injection is to be open with a voltage applied and closed with no voltage applied. Correspondingly the actuator impedance must be charged to open the injection valve and discharged again to close it. The energy supply of the piezo actuator must also function both as a current source and also as a current sink, with the energy moved being quite considerable.

Since around 100 mJ is moved for each triggering of the valve appr. 100 mJa kinetic energy of 1 J per injection process is achieved with multiple injection pulses—for example 5 pulses per injection. Considering a real application, such as a four-cylinder engine running at 3000 RPM, a kinetic energy of 100 J/s or 100 W is produced for actuating the four fuel injection valves.

Linear current sources have a low efficiency (<60%), which with these power requirements leads to very high power dissipation and correspondingly expensive heat removal (cooling down). They are therefore unsuitable for motor vehicle applications.

Switched current sources basically have a significantly greater efficiency and are suitable for a compact layout. Therefore conventional fuel-injection systems with piezo actuators in motor vehicles are implemented using this method.

A switched current source for charging and discharging a capacitor basically consists of at least one direct current source, an inductance, which can also be designed as a transformer, and a number of switches, to connect the inductance or piezo impedance to the voltage source or to ground. In some cases auxiliary capacitors or inductors are used.

There are two different known circuit concepts for switched current sources:
Output-side resonant final stages, and
Clocked final stages.

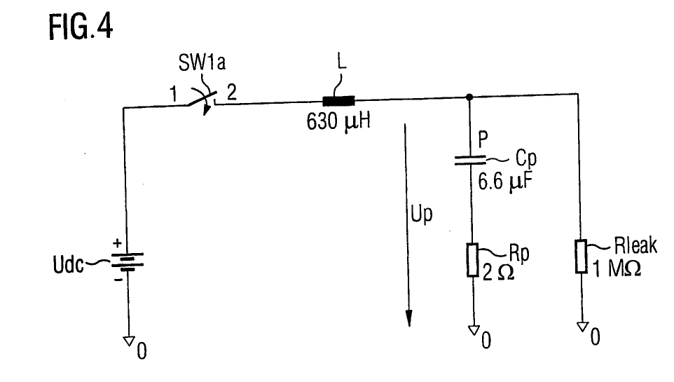

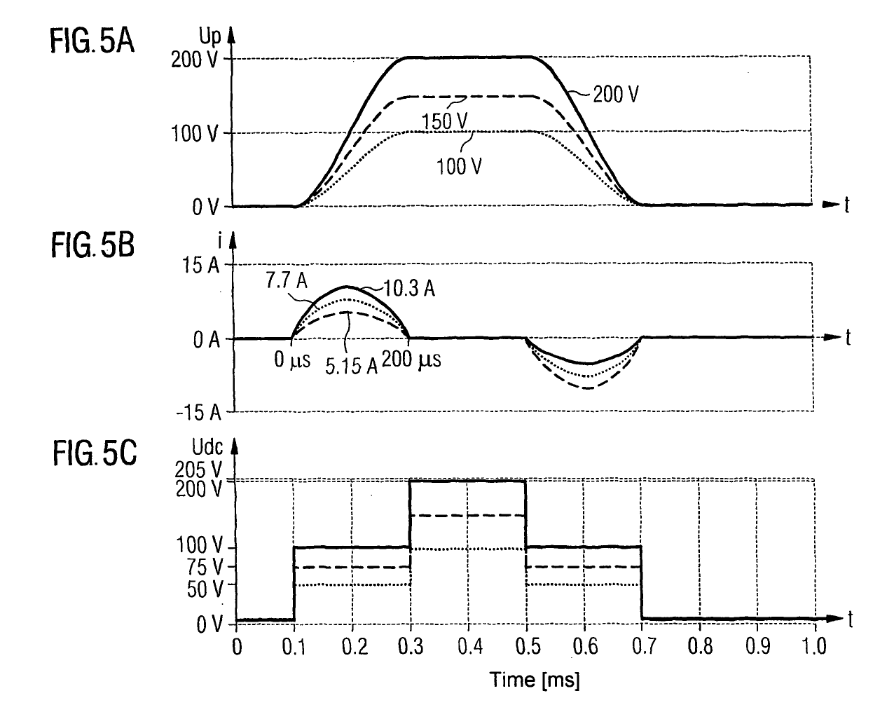

Output-side resonant final stages, known for example from DE 199 44 734 A1 and shown in simplified form in FIG. 4, use the capacitor Cp of the piezo actuator P in order to establish a series resonant circuit with a relatively large dimensioned inductance of a coil L. If a voltage excitation which changes abruptly is applied to this resonant series circuit L-Cp-Rp by closing switch SW1a (FIG. 5c), the voltage Up at the piezo actuator will oscillate to around double the value (200V) of the excitation voltage Vdc (100V) before oscillating back to a lower voltage, and thereafter periodically approaching the excitation voltage as it decays.

If the excitation is disconnected at the point in time of the first voltage maximum by opening the switch SW1a (FIG. 5c) —the current at this time has passed through half a sinusoidal oscillation—the actuator voltage Up remains at the voltage value obtained (FIG. 5a). This means that charging up to the desired voltage value Up has been achieved (opening of the valve). With different excitation voltages 50V, 75V, 100V (dotted, dashed or solid lines in FIG. 5c) this allows different charge voltages to be obtained: 100V, 150V, 200V, FIG. 5a. The sinusoidal half-wave oscillations of the current reach different, correspondingly scaled, positive amplitudes.

To close the valve (FIG. 5) the series oscillation circuit is connected once again, by closing the switch SW1a, to the excitation voltage—the piezo actuator discharges—and disconnects it, as soon as the actuator voltage of the current flowing through piezo actuator has reached the value 0V. The sinusoidal half-wave oscillations of the current are negative on discharging!

The excitation voltage is applied to the coil L an (FIG. 5c), as long as a current is flowing through it (FIG. 5b). The voltage shown in FIG. 5c in the interval between the excitation voltages for charging and discharging, with no current flowing, is the actuator voltage Up itself present at the piezo actuator—as in FIG. 5a.

This circuit can be refined by means of diodes and further switches, as known from DE 199 44 734 A1.

This concept offers great advantages as regards costs, complexity and efficiency. It is thus only possible with difficulty to take account of individual differences between injection valves with this design; i.e. to dynamically change the final charging voltage. The part lifts or intermediate levels required for linear operation of the valves are also barely able to be represented. Because of this restricted dynamic the concept is viewed as not being future-proof for future piezo actuators.

Concepts with output-side clocking are based overall on known switching controller topologies, which have been expanded for bidirectional (two-quadrant) operation for this purpose.

Their function can be most easily be seen from the example of a buck-boost converter, known from DE-198 54 789 A1. This type of circuit is also known from DE 199 44 733 A1, which in principle represents a bidirectional flyback converter with transformer. The main inductance of the transformer is charged up here from the input-side intermediate circuit to a specific value. Subsequently it discharges via the secondary circuit into the piezo actuator. The piezo actuator is discharged in the reverse direction. The piezo actuator is charged/discharged in packets in this case. A specific number of charge pulses corresponds to a specific charge status of the piezo actuator.

The disadvantages of this process are:
The charge current in the piezo actuator is very high with a small actuator voltage; in practice therefore the maximum current is reduced (limited) at the beginning of the charging process;
The actuator voltage increases—principally—in a parabolic curve, with the voltage being particularly steep at the beginning of the charging process;
Since charging is a two-stage process (first the transformer, then the piezo actuator), the piezo actuator is only charged in each second phase;
Since in addition the current curve during charging/discharging of the transformer is triangular in shape, the ratio of peak current to effective current value is around 4:1; that means increased stress for the components or more expensive components;
Correct filtering of the pulsed, triangular charge current curve to take into account EMC requirements demands expensive output filters.

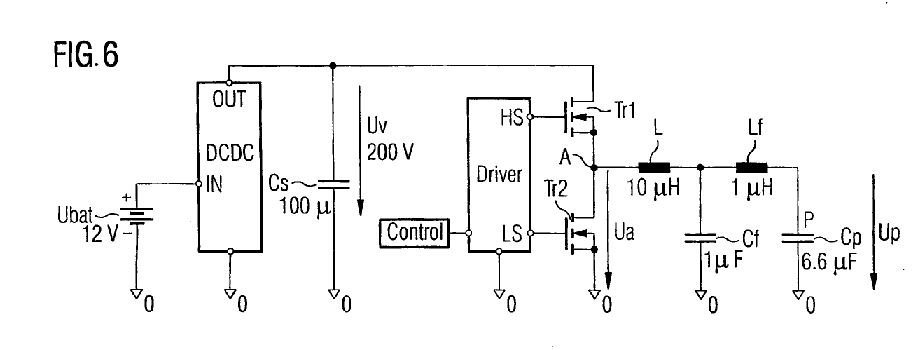

A buck-boost converter with constant charge current and operation at the intermittent boundary is shown in somewhat greater detail in FIG. 6.

With this circuit the vehicle electrical system voltage Vbat (12V) feeds a DC/DC converter, which delivers a voltage of for example 200V on the output side. The intermediate circuit capacitor Cs is used for dynamic buffering of the high, short-term transported energy on charging and discharging of the piezo actuator P (e.g. 100 mJ in 200 μs).

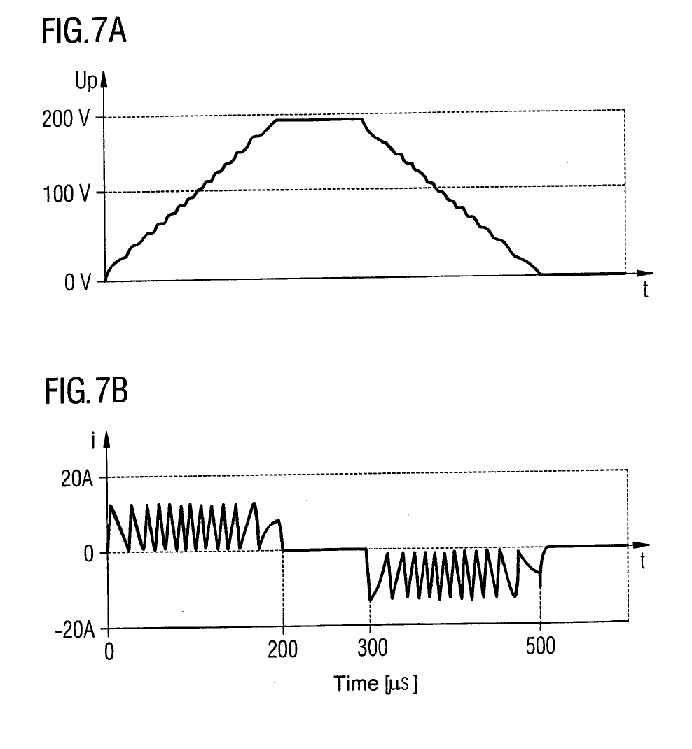

The Signal Control controls two series-connected switching transistors Tr1 and Tr2 via a driver circuit Driver. Via the junction A of these switching transistors a coil L connected in series with the piezo actuator can be connected in a clocked mode either for charging to the output voltage 200V of the DC/DC converter or for discharging to reference potential 0V (ground). The current flowing through the coil L (FIG. 7b) possesses a relatively high, high-frequency current ripple, so that an additional filter (filter capacitor Cf and filter coil Lf in FIG. 6) is required, before it can be used for charging the piezo actuator P.

To charge the piezo actuator P the latter is charged with a specific number of charge pulses. This produces the pulse duty ratio in that
the coil L, on connection to the vehicle electrical system voltage Vbat (high-side switching transistor Tr1 conducts) charges up to an upper current value (charging phase), and
on achieving this upper current value, high-side switching transistor Tr1 is switched to non-conducting and thereby the coil L discharges down to a lower current value 0V—(freewheeling phase), FIG. 7b, left part.

For discharging the piezo actuator P the pulse duty ratio is then activated for a specific number of current pulses in the reverse sequence so that the coil L
when connected to reference potential=ground (low-side switching transistor Tr2 conducts) charges u to a lower negative current value (charge phase), and
On reaching this lower negative current value, low-side switching transistor Tr2 is switched to non-conducting and thereby the coil L discharges to an upper negative current value, 0V, (freewheeling phase), FIG. 7b, right-hand part.

The voltage Up at piezo actuator P can be seen from FIG. 7a.

Since with this method the current switching points can only be modified with great difficulty during a charging process of the piezo actuator (required adjustment speed, accuracy), the number of charge reversal processes of the coil L or a predetermined period of time, for example 200 μs, are used to control the quantity of charge—and thereby the actuator voltage Up. In this case the voltage achieved is determined and the number of charge reversal processes of coil L or the predetermined period of time are adjusted accordingly.

In order to achieve a sufficiently high accuracy under these circumstances as well, the energy stored in the coil L must be kept low. Coils with relatively small inductances of for example 5 to 20 μH are therefore used. The result of this however is a relatively high, high-frequency current ripple of the charge current in the piezo actuator, making additional filter measures necessary (Lf, Cf), a feature of all concepts with output-side clocking.

Note should be taken with these output-side clocked concepts of the relatively unfavorable ratio of value between the useful reactances L and Cp and the filter components Lf and Cf. This leads to increased reactive current and additional kinetic charging, which in turn has a negative affect on the overall efficiency. Output-side clocked concepts, because of packetized energy transport between voltage supply and piezo actuator, allow a degree of flexibility in charging. Basically they allow any charging and discharging curves of the piezo actuator to be represented, which enables the major disadvantage of output-side resonant concepts to be rectified.

The technical embodiment of such circuits however turns out to be very complex and a significant circuit outlay is needed in order to overcome all ancillary effects in practice.

As a result of the relatively high switching frequencies of 100 to 500 kHz, the high switching currents of up to 40 A and the high switching voltages of up to 200V, significant losses sometimes occur, so that the efficiency of these concepts is mostly far lower than that of output-side resonant concepts. The high-frequency energy contained in the fast switching edges very easily leads to increased EMC radiation, which as a result must be reduced by appropriate constructive measures (filters). It is therefore difficult with an output-side clocked concept to find an implementation which is similarly economical to an output-side resonant concept.

An object of the invention is to specify a device for triggering a piezo actuator which, in conjunction with the method by means of which this device is operated, combines the advantage of resonant final stages with the flexibility of output-side clocked final stages.

In accordance with the invention this object is achieved in that, with the known circuit, a series circuit of a coil (L) of high inductance and the piezo actuator (P) to be triggered is arranged between the junction (A) of the two switching transistors (Tr1, Tr2) and reference potential (0V).

The method in accordance with the invention consists of,
for charging up to a desired actuator voltage (Up) or for discharging of the piezo actuator (P), an excitation signal Ua is applied to the junction (A) by means of inverse switching processes of the two switching transistors (Tr1, Tr2),
the excitation signal has an effective voltage which corresponds to around half the value of the desired actuator voltage Up,
the excitation signal Ua is formed from the product of supply voltage Uv and pulse duty ratio, with the pulse duty ratio corresponding to the temporal relationship of conducting phase and non-conducting phase of the high-side switching transistor (Tr1) or the temporal relationship of the conducting phases of the two switching transistors (Tr1, Tr2), and
the excitation signal Ua has a predeterminable switching frequency for the activation the two switching transistors (Tr1, Tr2).

Advantageous developments of the invention can be taken from the subclaims.

An exemplary embodiment in accordance with the invention is explained in more detail below with reference to a schematic drawing. The drawing shows the following:

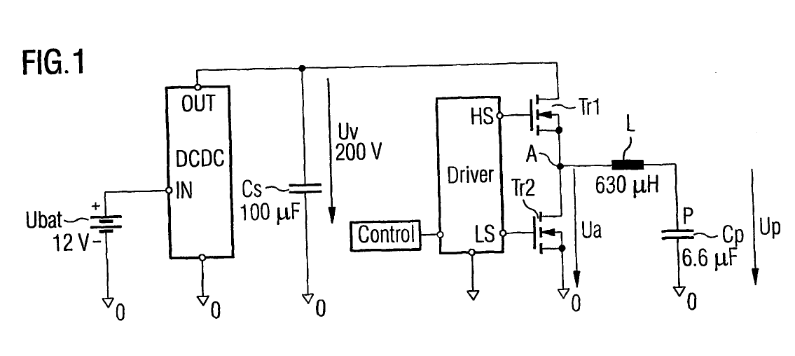

FIG. 1 a circuit diagram of an inventive device for triggering a piezo actuator,

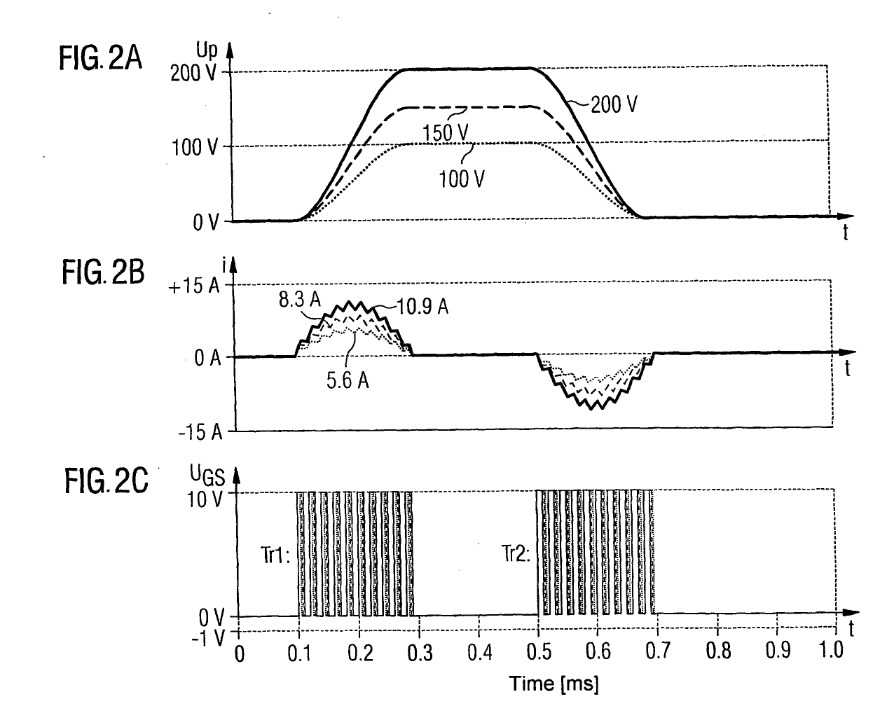

FIG. 2 voltage (2a) and current (2b) at the piezo actuator as a function of the pulse duty ratio (2c) of the excitation signal during operation of the device in accordance with FIG. 1 by means of the inventive method,

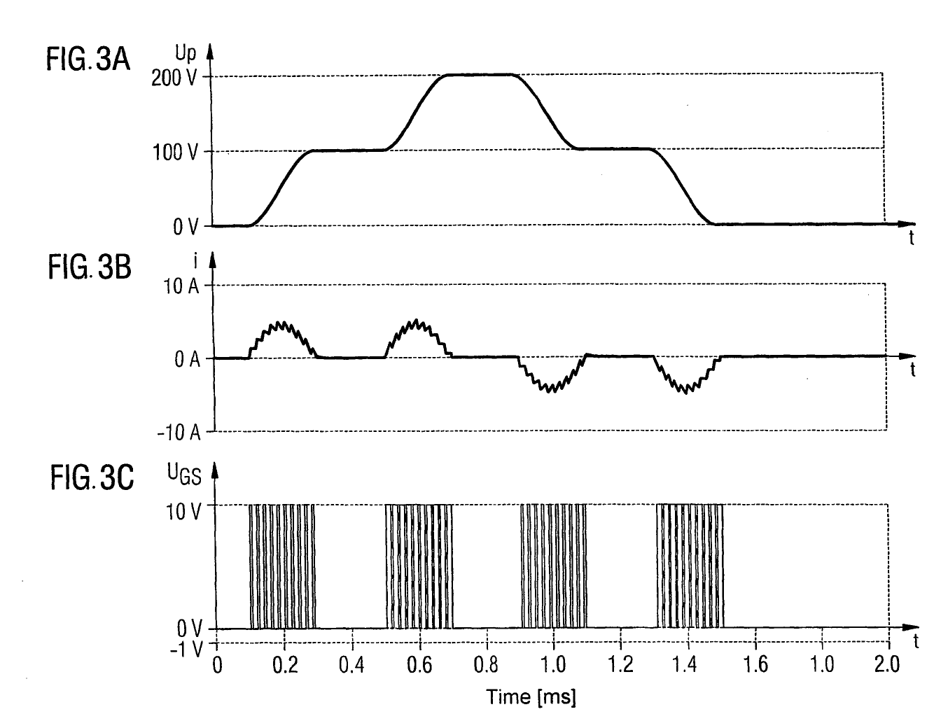

FIG. 3 voltage (3a) and current (3b) at the piezo actuator as a function of the pulse duty ratio (3c) of the excitation signal for creation of part lifts of the piezo actuator during operation of the device according to FIG. 1 by means of the inventive method,

FIG. 4 the basic circuit diagram of a known, output-side resonant triggering circuit for a piezo actuator,

FIG. 5 voltage (5a), current (5b) and excitation voltage (5c) at the piezo actuator on opening and closing of the piezo actuator by oscillation of the actuator voltage for the basic circuit depicted in FIG. 4,

FIG. 6 the switching of a known, output-side clocked trigger circuit for a piezo actuator, and

FIG. 7 voltage (7a) and current (7b) at the piezo actuator for the circuit according to FIG. 6,

FIG. 1 shows a basic circuit of an inventive device, which is to be operated by means of the inventive method.

In this basic circuit the vehicle electrical system voltage Vbat (12V) feeds a DC/DC converter DCDC, which on the output side delivers a supply voltage of appr. 200V. The intermediate circuit capacitor Cs between the output of the DC/DC converter DCDC and reference potential (0V) is used for dynamic buffering of the high short-duration energy for charging and discharging the piezo actuator P.

In parallel to the intermediate circuit capacitor Cs is arranged a series circuit of two switching transistors Tr1 and Tr2. A Signal Control controls two switching transistors, a high-side transistor Tr1 and a low-side transistor Tr2 via a driver circuit Driver. Via the junction A of these two switching transistors Tr1 and Tr2 a coil L of high inductance, for example 630 μH, connected in series with the piezo actuator P can be connected in a clocked manner alternately to the supply voltage (output voltage 200V of the DC/DC converter DCDC) or to reference potential 0V (ground).

This circuit is largely identical to the known buck-boost converter described above, shown in FIG. 6. Only the filter components Lf and Cf are omitted and the inductance of the coil L is significantly increased compared to this known design and roughly corresponds to the inductance of coil L for the output-side resonant circuit according to FIG. 4.

The control idea underlying the inventive method employs the method of resonant oscillation in this case—see FIGS. 4 and 5.

In addition use is also made of the fact that, with sufficiently high inductivity, the voltage of the excitation signal can be replaced by the mean value of a higher, constant voltage with corresponding pulse duty ratio.

In the inventive method the charging and discharging of the capacitor Cp of the piezo actuator P is undertaken not—as in an output-side clocked buck-boost converter—by means of a regulated current, but through resonant ring-around.

In this case the reciprocal frequency to the ring-around duration (time needed for charging and discharging the piezo actuator P to a desired actuator voltage Up without pauses in between) is determined by the inductance of the coil L and the capacitance Cp of the piezo actuator P, and the excitation signal Ua of the coil L at the junction A between the two switching transistors Tr1 and Tr2 is obtained as the product of supply voltage (200V) and pulse duty ratio (=effective value of the supply voltage). Current regulation is entirely dispensed with in this case.

The pulse duty ratio corresponds to the temporal relationship of conducting phase to non-conducting phase of the high-side switching transistor (Tr1) or to the temporal ratio of the conducting phases of the high-side switching transistor Tr1 to low-side switching transistor Tr2. The difference results from the type of freewheeling. In the first case low-side switching transistor Tr2 is not activated and the freewheeling is undertaken via a diode connected in parallel to T2, the substrate diode present for MOS-FET transistors. In the second case low-side switching transistor Tr2 is switched on during the active phase (active freewheeling).

Since the actuator voltage reaches double the value of the excitation voltage Ua the excitation voltage Ua must therefore be set by means of the pulse duty ratio voltage to half the value of the desired actuator voltage Up, for a desired actuator voltage of Up=200V the excitation voltage is thus to be set to 100V (effective value from 200V supply voltage*50% pulse duty ratio), for Up=150V to 75V (200V*37.5%) and for 100V to 50V (200V*25%), see FIGS. 2a and 2c.

The two switching transistors Tr1 and Tr2 operate inversely to each other in the charging and discharging phase, i.e., if high-side switching transistor Tr1 is conductive, low-side switching transistor Tr2 is non-conductive and vice versa. With piezo actuator P under voltage (operating phase) and without voltage (idle phase)—whereby no current flows—both switching transistors Tr1 and Tr2 are non-conductive. In the operating phase however high-side switching transistor Tr1 can then be set to conduct if the voltage Up at the piezo actuator P, dropping as a result of losses must be corrected.

FIG. 2c shows the gate source voltage during the charging phase (left side) of the high-side switching transistor Tr1. In this exemplary embodiment the gate source voltages amount to 10V for example. For improved clarity the freewheeling through the substrate diode has been selected. With a supply voltage of Uv=200V the pulse duty ratio is:
for an actuator voltage of 100V: 25% (dotted line),
for an actuator voltage of 150V: 37.5% (dashed line) and
for an actuator voltage of 200V: 50% (solid line).

If the gate source voltage U_{GS}=10V, the junction A or the coil L is at the supply voltage Uv=200V. If the gate source voltage U_{GS}=0V—driven by the electromotive force (EMF) of the coil —the junction A or the coil L is at reference potential 0V (ground). The gate source voltage U_{GS} of the low-side switching transistor Tr2 is 0V in this phase.

The gate source voltage UGS of the low-side switching transistor Tr2 during the discharging phase is shown (in FIG. 2c on the right), with pulse duty ratios 75%, 62.5% and 50% corresponding to the non-conducting phase of the high-side switching transistor Tr1 in the load phase.

The current which is set during the charging or discharging phase follows—as with the known, output-side resonant activation circuit depicted in FIG. 4, a sine-wave curve, see FIG. 5b, but now has, through the alternating connection of the coil L with Uv=200V and reference potential=0V, an overlaid, triangular component (FIG. 2b).

Both the charging time and also the discharging time are ended if the charging or discharging current reaches the value 0V.

Let 50 kHz be selected as the switching frequency for the switching transistors Tr1 and Tr2, which represents a good compromise between switching losses and residual ripple of the current flowing through the piezo actuator P.

Suitable changes to the duty ratio, switching duration and intermediate operating phases allow the voltage level or curves of the actuator voltage (Up) to be achieved in any timing sequence. This means that part lifts and a more linear operation of the fuel injection valve are possible, see FIGS. 3a, b, c.

An important system requirement is the highly-accurate determination of the energy E fed to the piezo actuator P, since this represents a direct relationship to its change in length.

The energy E can be determined in a known way by multiplying the voltage u present at the piezo actuator P by the integral of the current I:
{1} E=∫u*idt

However the capacitance Cp of the piezo actuator P is also to be determined via the size of the inductance of the coil L and the oscillation frequency ω reciprocal to the ring-around time T_{umschwing}:

from ω=1/√L*Cp, T=2*π/ω and T=2*T_{umschwing} the following is produced:
{2} Cp=T²_{umschwing}/(π²*L)

However this also enables the energy E fed to the piezo actuator P to be determined from capacitance Cp and actuator voltage Up:
{3} E=½*Cp*Up²

The capacitance value Cp of the piezo impedance has a significant dependence on temperature which varies in the temperature range observed by about 4 μF to 6.6 μF. In resonant mode this manifests itself in a change of the ring-around time.

Thus with a temperature-dependent capacitance change, which, according to formula 3, causes a change to the energy fed to the piezo actuator P, a constant amount of energy can always be fed to the piezo actuator P by changing the pulse duty ratio (increasing the pulse duty ratio for a lower capacitance and vice versa).

The use of this additional method leads to a significant increase in the accuracy of the measurement, since a relatively imprecise dynamic current measurement is dispensed with and the very precise automatic measurement of the actuator voltage Up is possible.

An error only has a relatively slight effect in the determination of the capacitance Cp of the piezo actuator P whereas the influence of the voltage error is quadratic!

A further increase in the accuracy is possible by taking into account the resistance value Rp of the piezo impedance and further loss factors in the determination of the capacitance of the piezo actuator.

The actual value of the inductance of the coil L can also be detected and stored by a production calibration.

Likewise an increase in accuracy is possible by joint use of the two measurement methods.

The advantages of the device operated with the inventive method are considerable:
The inventive device fulfills all requirements imposed on a future driver circuit for piezo actuators; it is also the device requiring the lowest component outlay, which also means low costs,
The inventive device allows a very simple circuit layout and needs few additional auxiliary circuits, because of the low current ripple of the charge current only minimal EMC filter measures are required,
The inventive method is strictly deterministic and can therefore be operated highly accurately with known environmental parameters,
The requirements imposed on control are restricted to determining and changing the pulse duty ratio, start of switching and switching duration (switching frequency);
Separate current regulation is not necessary,
The influence of supply voltage fluctuations can be eliminated by their measurement and by taking them into account in the pulse duty ratio,
The options for precise energy measurement are significantly expanded: for diagnostic purposes the actuator voltage can be measured after the first switching pulse has occurred and compared to a predefined voltage window assigned to a reference value; if the actuator voltage lies outside this predefined voltage window, this enables a short circuit or a line interruption to be detected in a simple manner,
The method allows high efficiency and low loss energy,
A low EMC radiation is produced through the option of applying slow switching edges with a low switching frequency, and, through the large inductance of the coil L, a low current ripple of the output current,
No fast current regulation is required for guiding the charge current, since a resonant inherent control of the charge current occurs,
Because of the resonant ring-around of voltage and current a high short-term stability is produced,
A precise control of the final charge voltage Up of the piezo actuator P is possible via the pulse duty ratio,
A simple option for triggering of temporally-independent intermediate plateaus of the length of the piezo actuator P up to its end position is produced,
A low switching frequency of <50 kHz is possible,
A dynamic control to exclude the influence of the supply voltage on den charging process is possible,
Low switching currents are produced, which are primarily determined by the charge current of the piezo actuator.

1-11. (canceled)

12. A device for triggering a piezo actuator, the device comprising:
a DC/DC converter receiving a vehicle electrical system voltage, said DC/DC converter having an output delivering a high supply voltage;
an intermediate circuit capacitor;
a first series circuit disposed in parallel to said intermediate circuit capacitor and formed of a high-side switching transistor and a low-side switching transistor disposed between said output of said DC/DC converter and a reference potential, a connection point between said high-side switching transistor and said low-side switching transistor defining a connection junction;
a driver circuit receiving a control signal connected to and controlling said first series circuit; and
a coil of high inductance connected to said connection junction, said coil and the piezo actuator to be triggered defining a second series circuit disposed between said connection junction of said high and low side switching transistors and the reference potential.

13. A method for operating a device for triggering a piezo actuator, the device containing:
a DC/DC converter receiving a vehicle electrical system voltage, the DC/DC converter having an output delivering a high supply voltage;
an intermediate circuit capacitor;
a first series circuit disposed in parallel to the intermediate circuit capacitor and formed of a high-side switching transistor and a low-side switching transistor disposed between the output of the DC/DC converter and a reference potential, a connection point between the high-side switching transistor and the low-side switching transistor defining a connection junction;
a driver circuit receiving a control signal controlling the first series circuit; and
a coil of high inductance connected to the connection junction, the coil and the piezo actuator to be triggered defining a second series circuit disposed between the connection junction of the high and low side switching transistors and the reference potential;
the method which comprises the steps of:
applying an excitation signal to the connection junction by means of an inverse switching processes of the high-side and low-side switching transistors for charging to a desired actuator voltage or for discharging the piezo actuator, the excitation signal having an effective voltage corresponding to around half a value of the desired actuation voltage; and
forming the excitation signal from a product of the high supply voltage and a pulse duty ratio, with the pulse duty ratio corresponding to a temporal relationship of a conducting phase and a non-conducting phase of the high-side switching transistor or a temporal relationship of conducting phases of the high-side and low-side switching transistors, the excitation signal having a predeterminable switching frequency for the triggering of the high-side and low-side switching transistors.

14. The method according to claim 13, which further comprises applying the excitation signal until a charging current or a discharging current becomes zero.

15. The method according to claim 13, which further comprises providing the predeterminable switching frequency in a range of 50 kHz for activation of the high-side and low-side switching transistors.

16. The method according to claim 13, which further comprises changing at least one of the pulse duty ratio, a switching duration and inserted operating phases, for obtaining voltage levels of the desired actuator voltage in any given curve, including part lifts.

17. The method according to claim 13, which further comprises:
determining an amount of energy E fed to the piezo actuator from a capacitance Cp of the piezo actuator and the desired actuator voltage Up according to formula
E=½*Cp*Up²,
determining the capacitance Cp of the piezo actuator from a size of an inductance of the coil and a reciprocal oscillation frequency ω for a ring-around duration T_{umschwing}, where
ω=1/√L*Cp, T=2*π/ω and T=2*T_{umschwing}
and
Cp=T²_{umschwing}/(π²*L).

18. The method according to claim 17, which further comprises taking into account a resistance value of actuator impedance and further loss factors in the determining of the capacitance Cp of the piezo actuator.

19. The method according to claim 18, which further comprises detecting an actual value of the inductance of the coil by performing a production calibration and storing the actual value for calculating the actuator capacitance Cp.

20. The method according to claim 19, which further comprises jointly considering the actuator impedance, the further loss factors and actual value of the inductance of the coil for the determining the actuator capacitance Cp.

21. The method according to claim 13, which further comprises:
measuring an amount of energy fed to the piezo actuator during a charge process resulting in measured energy;
comparing the measured energy to a predetermined amount of energy; and
correcting for differences between the measured energy and the predetermined amount of energy resulting from temperature-induced changes to the capacitance Cp of the piezo actuator by changing the pulse duty ratio in a next charging process.

22. The method according to claim 13, which further comprises detecting one of a short circuit and a line break in a charge path, if the desired actuator voltage measured during a charge process after a completed switching pulse lies outside a predefined voltage window assigned to a reference value.
